(19) United States
(12) Patent Application Publication
(10) Pub. No.: US 2003/0127322 A1
(43) Pub. Date: Jul. 10, 2003

(54) Sputtering apparatus and magnetron unit

(76) Inventors: Mayumi Shimakawa, Narita-shi (JP); Masatoshi Tsuneoka, Narita-shi (JP); Takeshi Jinbo, Ichihara-shi, Chiba (JP)

Correspondence Address: WILLIAM B. PATTERSON, MOSER, PATTERSON & SHERIDAN, LLP, 3040 POST OAK BLVD., SUITE 1500, HOUSTON, TX, 77056, US

(21) Appl. No.: 09/700,808

(22) PCT Filed: May 20, 1999
(86) PCT No.: PCT/JP99/02646

(30) Foreign Application Priority Data
May 20, 1998 (JP) P1998-138580

(51) Int. Cl. C23C 14/35

(52) U.S. Cl. 204/298.01; 204/298.12; 204/298.16; 204/298.28

(57) ABSTRACT

In a sputtering apparatus having a magnetron unit, the erosion surface of a target is partitioned into a circular inner region concentric with a wafer W supported by a pedestal, and an annular outer region which is adjacent the inner region on the outside thereof and surrounds the inner region; whereas the magnetron unit is constituted by a first subunit for generating a magnetic field for controlling plasma near the inner region, and a second subunit for generating a magnetic field for controlling plasma near the outer region. Since the atoms sputtered from the inner region have a directivity, a high bottom coverage ratio is obtained. Also, an in-surface uniformity is obtained by the atoms sputtered from the outer region even when the target and wafer are disposed closer to each other.

### TECHNICAL FIELD

The present invention relates to a magnetron type sputtering apparatus used in the making of a semiconductor device or the like, and a magnetron unit therefor.

### BACKGROUND ART

With higher integration of semiconductor devices in recent years, wiring patterns have become finer or narrower, whereby it has been becoming harder to efficiently form a film in contact holes via holes and the like by conventional sputtering methods. For example, when a film is formed on a semiconductor wafer surface having a fine hole in a typical magnetron type sputtering apparatus, there is a problem that an overhang is formed at the entrance portion of the hole, whereby the bottom coverage ratio deteriorates. Therefore, new techniques such as collimation sputtering method and remote or long throw sputtering method have been developed.

The collimation sputtering method refers to a technique in which a plate referred as collimator having a number of holes is mounted between a target and a wafer, and sputtered atoms are passed through the holes of collimator, so that a directivity is given to the sputtered atoms, which are inherently non-directional whereby only the sputtered atoms in the vertical component are mainly deposited on the wafer.

On the other hand, the remote sputtering method is a method in which the distance between the target and wafer is made much longer than that in the conventional typical sputtering apparatus. In this method, the sputtered atoms advancing at a large angle with respect to the wafer reach the region outside the wafer, whereby only the sputtered atoms advancing substantially vertically would be deposited on the wafer.

Each of the above-mentioned collimation sputtering method and remote sputtering method is a film-forming technique yielding a high bottom coverage ratio and responding to miniaturization of wiring patterns.

In the collimation sputtering method, however, sputtered material may adhere to the collimator, and clogging may occur if the amount of adhesion increases, thus causing a fear of the uniformity of film formation and the deposition ratio deteriorating. Also, if the film attached to the collimator peels off, then it becomes a debris on the wafer, which causes the device to fail. Further, it is problematic in that the collimator attains a high temperature due to plasma, thereby affecting the temperature control of wafer. Also, since the sputtered atoms have a strong tendency to go straight ahead, the side coverage ratio may become insufficient.

In the case of low-pressure remote sputtering method, on the other hand, though no operation for maintenance such as replacement of the collimator is necessary since nothing exists between the target and wafer, it is problematic in that the deposition ratio is extremely low since the distance between the target and wafer is long. Also, in order for the sputtered material to securely deposit in the vertical direction, the discharging pressure must be made as low as possible such that the sputtered material does not collide with gas molecules during their flight. As a consequence, a dedicated magnetron unit has to be prepared so as to enable stable discharging even in a low pressure state, whereby the apparatus has become expensive. Further, the deposition ratio differs between the center portion and peripheral portion of the wafer, whereby the uniformity in film thickness over the whole wafer surface is unfavorable.

Hence, it is a main object of the present invention to provide means for improving the in-surface uniformity of bottom coverage ratio, deposition ratio, and film thickness with a favorable balance.

### DISCLOSURE OF THE INVENTION

For achieving the above-mentioned object, the inventors have carried out various studies and, as a result, have found that, when the distance between the target and wafer is shortened in order to enhance the deposition ratio, the bottom coverage ratio can be improved at the same time if the area of the target surface subjected to erosion by sputtering (erosion surface) is made smaller.

FIG. 4 shows the reason thereof. In the case where two larger and smaller targets 1, 2 and a wafer W are arranged in a positional relationship such as that shown in FIG. 4, the angle of incidence when a material sputtered from the outer periphery of the larger-diameter target 1 reaches the outer periphery of wafer W equals the angle of incidence when a material sputtered from the outer periphery of the smaller-diameter target 2 reaches the same position of wafer W. It means that the directivity or bottom coverage ratio is improved if the target is disposed closer to the wafer while the erosion surface is made smaller. As a matter of course, it also means that the deposition ratio improves since the distance between the target and wafer is short.

However, if the erosion surface is simply made smaller, then the film thickness increases from the periphery of wafer to the center thereof, thus still leaving a problem of unevenness in film thickness.

Therefore, the present invention provides a sputtering apparatus comprising a vacuum chamber, means for supporting a wafer within the vacuum chamber, a target having an erosion surface disposed so as to face the wafer supported by the supporting means, means for supplying a process gas into the vacuum chamber, means for reducing a pressure within the vacuum chamber, plasma-forming means for forming plasma from the process gas supplied into the vacuum chamber, and a magnetron disposed on a side of the target opposite from the erosion surface; wherein the erosion surface of the target is partitioned into a circular inner region concentric with the wafer supported by the supporting means and an annular outer region, adjacent the inner region on the outside thereof, surrounding the inner region; wherein the magnetron unit is constituted by a first subunit for generating a magnetic field for controlling plasma near the inner region, and a second subunit for generating a magnetic field for controlling plasma near the outer region; and wherein the first and second subunits are configured so as to cause a thin film formed on the wafer to have a uniform thickness throughout a surface of the wafer.

In such a configuration, the atoms sputtered from the inner region of the target are controlled by the magnetic field produced by the first subunit of the magnetron unit, so as to have a directivity. Therefore, if the distance between the target and wafer is shortened, then a high deposition ratio can also be secured while a high bottom coverage ratio is maintained.

On the other hand, the atoms sputtered from the outer region are controlled by the magnetic field produced by the second subunit of the magnetron unit and mainly influence the film formation in the peripheral portion of wafer As a consequence, additional sputtered atoms can be supplied to the peripheral portion of wafer where the film thickness becomes insufficient when solely depending on the atoms sputtered from the inner region, whereby the in-surface uniformity in film thickness can be secured.

Preferably, the diameter of the inner region of erosion surface is substantially identical to or smaller than the diameter of wafer.

An example of the magnetron unit configuration is one comprising a base plate disposed parallel to the target, a plurality of magnets secured to the base plate such that both magnetic pole ends of each magnet face the target, and a driving motor for driving the base plate to rotate; wherein the plurality of magnets are disposed in a double annular arrangement, such that the first subunit is constituted by the magnets in the inner ring of annular arrangement, while the second subunit is constituted by at least a part of the magnets in the outer ring of annular arrangement.

The above-mentioned and other characteristics features and advantages of the present invention will be clear to one skilled in the art by reading the following detailed explanations with reference to the accompanying drawings.

### BRIEF DESCRIPTION OF THE DRAWINGS

FIG. 1 is a schematic view showing a preferred embodiment of the present invention;

FIG. 2 is a view showing a state where the magnetron unit in FIG. 1 is viewed from thereunder;

FIG. 3 is a schematic view showing the configuration of a magnet used in the magnetron unit; and

FIG. 4 is an explanatory view showing the relationship between the size of targets, their position with respect to a wafer, and the angle of incidence of sputtered atoms.

### BEST MODES FOR CARRYING OUT THE INVENTION

In the following, a preferred embodiment of the prevent invention will be explained in detail with reference to the drawings.

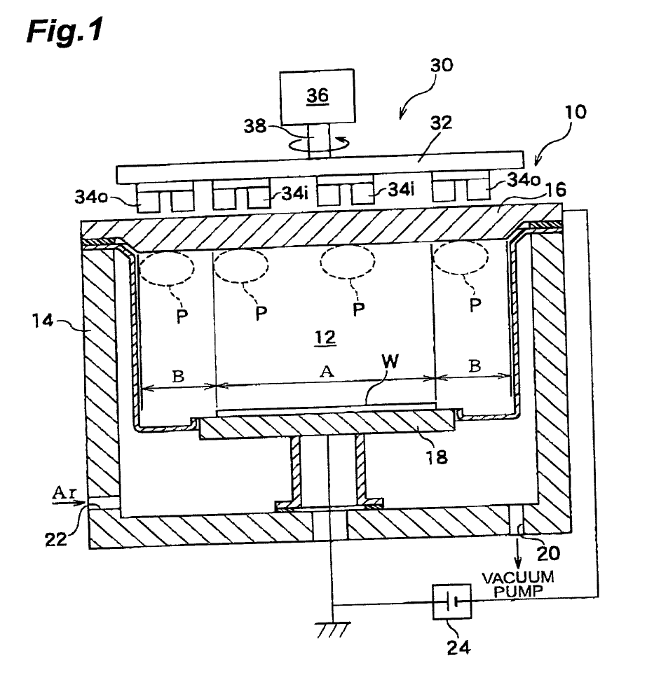

FIG. 1 schematically shows a magnetron type sputtering apparatus according to the present invention. The sputtering apparatus 10 comprises a housing 14 forming a vacuum chamber 12 therein, and a disk-shaped target 16 disposed so as to close the upper opening portion of the housing 14. The circular lower face of target 16 as a whole is an erosion surface subjected to erosion by sputtering.

Disposed within the vacuum chamber 12 is a pedestal 18 having an upper face for holding a semiconductor wafer W which is a substrate to be processed. The upper face of pedestal 18 is disposed so as to face the lower face of target 16 in parallel therewith, whereby the wafer W held at a predetermined position on the pedestal 18 becomes parallel to and concentric with the lower face of target 16. In the shown embodiment, the dimensions of target 16 and the distance between the pedestal 18 and target 16 are similar to those in a conventional sputtering apparatus.

The housing 14 is formed with an exhaust port 20. Connected to the exhaust port 20 is a vacuum pump (not shown) such as cryopump, which is actuated so as to reduce the pressure in the vacuum chamber 12. Also, argon gas as a process gas is supplied into the vacuum chamber 12 from a gas supply source, which is not shown, by way of a port 22.

The cathode and anode of a DC power supply 24 are connected to the target 16 and the pedestal 18 (i.e., wafer W), respectively. When voltage is applied between the target 16 and the pedestal 18, i.e., wafer W, while discharge argon gas is introduced into the vacuum chamber 12, glow discharge occurs. At this time, argon ions in plasma collide with the lower face of target 16, thereby forcing out target atoms (sputtered material) therefrom, which then deposit on the wafer W, thus forming a thin film.

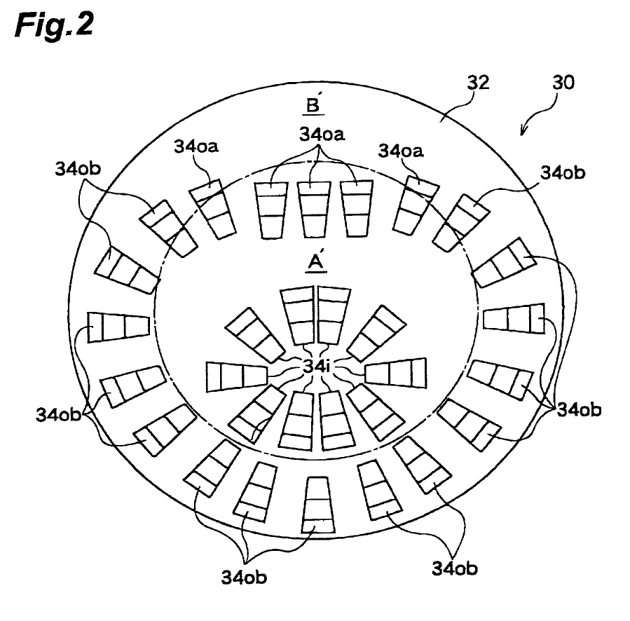

A magnetron unit 30 for enhancing the plasma density in the vicinity of the target 16 is disposed on the side of target 16 opposite from the lower face thereof, i.e., above the target 16. As is also shown in FIG. 2, the magnetron unit 30 is constituted by a circular base plate 32, and a plurality of magnets 34 secured onto the base plate 32 in a predetermined arrangement. The base plate 32 is disposed above the target 16 so as to be concentric therewith, whereas the rotary shaft 38 of a driving motor 36 is connected to the center of the upper face thereof. As a consequence, if the driving motor 36 is driven so as to rotate the base plate 32, then each magnet 34 circles along the upper face of target 16, whereby the magnetic field caused by each magnet 34 can be prevented from staying at one location.

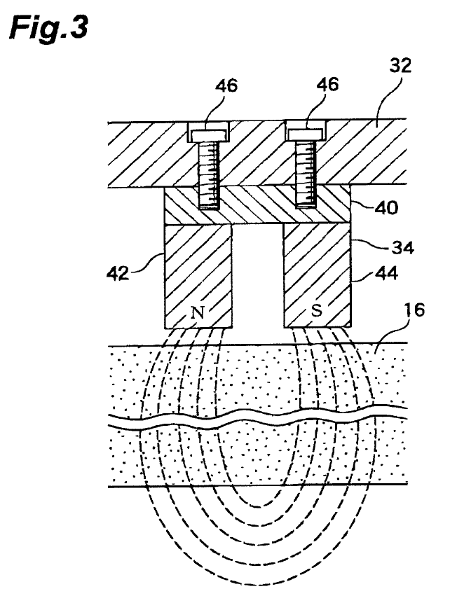

As is clearly shown in FIG. 3, each magnet 34 is constituted by a planar yoke member 40 made of a ferromagnet, and bar magnets 42, 44 firmly attached to the respective end portions of the yoke member 40. The two bar magnets 42, 44 are directed in the same direction, so that the magnet 34, as a whole, has substantially a U-shaped form. The free end of one bar magnet 42 is the N-pole, whereas the free end of the other bar magnet 44 is the S-pole. In this embodiment, the bar magnets 42, 44 have respective end face areas substantially identical to each other. As a consequence, lines of magnetic forces extending between the magnetic pole end faces of bar magnets 42, 44 in each magnet 34 substantially equilibrate (see broken lines in FIG. 3). Leakage flux hardly occurs in the region on the side of bar magnets 42, 44 opposite from the end faces thereof, since the magnetic circuit is formed from the ferromagnetic yoke member 40.

Such a magnet 34 is secured to the base plate 32 by appropriate securing means, for example screws, in a state where the back face of yoke member 40 is in contact with the base plate 32. In such a configuration, the securing position of each magnet 34 can be changed freely, whereby various arrangements of magnets 34 can be considered. In the shown embodiment, the magnets 34 are disposed in a double annular arrangement as shown in FIG. 2.

All of the magnets 34i (the suffix i representing the inner ring of annular arrangement) in the inner ring of annular arrangement and a part 34oa of the magnets 34o (the suffix o representing the outer ring of annular arrangement) in the outer ring of annular arrangement form a magnetic field in a space in the vicinity of an inner region A of the lower face of target 16, control plasma in this space, and eventually control the sputtering with respect to the inner region A. Here, the inner region A of the lower face of target 16 refers to a circular region which is concentric with the wafer W held by the pedestal 18 and has a diameter substantially identical to or smaller than the diameter of wafer W.

The remaining magnets 34ob in the outer ring of annular arrangement form a magnetic field in a space in the vicinity of an outer region B of the lower face of target 16, control plasma in this space, and eventually control the sputtering with respect to the outer region B. The outer region B of the lower face of target is an annular region, adjacent the inner region A on the outside thereof, surrounding the inner region A. Here, letters A′, B′ in FIG. 2 indicate the respective regions corresponding to the regions A, B in the base plate 32 of magnetron unit 30, whereas the chain line is a boundary line partitioning both regions.

As mentioned above, a tunnel-shaped magnetic field is formed in each magnet 34 (see the broken lines in FIG. 3). This magnetic field enhances the density of plasma P in the vicinity of the lower face of target, thereby accelerating the sputtering in the part where the magnetic field is located.

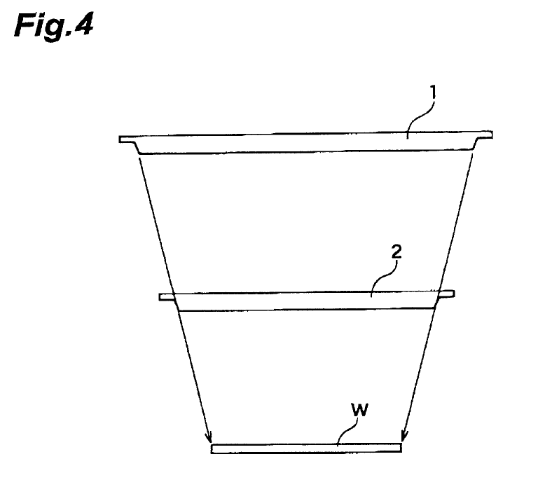

In the sputtered atoms generated upon sputtering with respect to the inner region A of the lower face of target 16, as explained with reference to FIG. 4, those vertically incident on the surface of wafer W are greater in number than their horizontal components, whereby a higher bottom coverage ratio is obtained. Also, since the distance between the target 16 and pedestal 18 is similar to that in typical sputtering apparatus, the deposition ratio would not deteriorate.

On the other hand, the deposited film in the peripheral portion of wafer W tend to lower its thickness when solely depending on the atoms sputtered from the inner region A of the lower face of target 16. Therefore, the configuration and securing positions of the magnets 34ob in the outer ring of annular arrangement are defined such that the atoms sputtered from the outer region B of the lower face of target 16 are mainly deposited on the peripheral portion of wafer W, so as to improve the in-surface uniformity in the film thickness. The atoms sputtered from the outer region B of target 16 have smaller angles of incidence with respect to the surface of wafer W, thereby contributing to an improvement in side coverage ratio as well.

The inner and outer rings of annular arrangement of magnets 34 shown in FIG. 2 are not perfectly circular, and their positions of center of gravity are not located at the center of the base plate 32. They are thus arranged such that their magnetic fields travel across the whole lower face of target 16 as the base plate 32 is driven by the driving motor 36 to rotate.

Though a preferred embodiment of the present invention is explained in detail in the foregoing, the present invention is not limited to the above-mentioned embodiment as a matter of course.

For example, the arrangement of magnets 34 can be changed as appropriate. Though the magnets 34i in the inner ring of annular arrangement and a part 34oa of magnets in the outer ring of annular arrangement function as the first subunit of magnetron unit 30 for controlling plasma P in the vicinity of the inner region A of the lower face of target 16, whereas the remaining magnets 34ob in the outer ring of annular arrangement function as the second subunit for controlling plasma P in the vicinity of the outer region B of the lower face of target 16, the arrangement may be such that all of the magnets 34o in the outer ring of annular arrangement function as the second subunit. Also, though a plurality ofmagnets are discontinuously arranged in an annular fashion in the above-mentioned embodiment, each subunit may be constituted by a single annular magnet, whereas the first and second subunits may be of other types, such as those employing electromagnets, as long as they can separately control the respective magnetic fields formed in the vicinity of the inner and outer regions A and B of the lower face of target 16.

The inner region A of target 16 may have any dimensions as long as the atoms sputtered from the inner region A have a certain degree of directivity.

Industrial Applicability

As explained in the foregoing, the present invention is characterized in that the target is partitioned into an inner region having a smaller diameter and an outer region, and sputtering for each region is made controllable. As a consequence, atoms sputtered from the inside region can improve the coverage ratio and deposition ratio, whereas atoms sputtered from the outer region can improve the in-surface uniformity in film thickness.

Further, since there is no necessity to dispose a collimator between the target and wafer, no detrimental effects occur due to the collimator. Also, since the target and wafer can be disposed closer to each other, it is not necessary to lower the pressure in the vacuum chamber during the process so much as in the remote sputtering method.

Therefore, the present invention can improve the coverage ratio, deposition ratio, in-surface uniformity in film thickness, and the like with a favorable balance in the film-forming process using the sputtering method, thereby being able to respond to higher integration and miniaturization of devices in the field of making electro-micro devices such as semiconductor devices.

1. A sputtering apparatus comprising:
a vacuum chamber;
means for supporting a wafer within said vacuum chamber;
a target having an erosion surface disposed so as to face the water held by said supporting means; said erosion surface being partitioned into a circular inner region concentric with the wafer supported by said supporting means and an annular outer region, said outer region being adjacent said inner region on the outside thereof and surrounding said inner region;
means for supplying a process gas into said vacuum chamber;
means for reducing a pressure within said vacuum chamber;
plasma-forming means for forming plasma from the process gas supplied into said vacuum chamber; and
a magnetron disposed on a side of said target opposite from said erosion surface; said magnetron unit comprising a first subunit for generating a magnetic field for controlling plasma near said inner region of said erosion surface, and a second subunit for generating a magnetic field for controlling plasma near said outer region; said first and second subunits being configured so as to cause a thin film formed on said wafer to have a uniform thickness throughout a surface of said wafer.

2. A sputtering apparatus according to claim 1, wherein said inner region of said erosion surface has a diameter substantially identical to the diameter of said wafer.

3. A sputtering apparatus according to claim 1, wherein said magnetron unit comprises
a base plate disposed parallel to said target;
a plurality of magnets secured to said base plate such that both magnetic pole ends of each said magnet face said target; and
a driving motor for driving said base plate to rotate;
said plurality of magnets being disposed in a double annular arrangement,
said first subunit being constituted by said magnets in the inner ring of annular arrangement,
said second subunit being constituted by at least a part of said magnets in the outer ring of annular arrangement.

4. A magnetron unit disposed on a side of a target opposite from an erosion surface thereof in a sputtering apparatus, said magnetron unit comprising:
a base plate;
a plurality of magnets secured to said base plate such that both magnetic pole ends of each said magnet face said target, said plurality of magnets being disposed in a double annular arrangement; and
a driving motor for driving said base plate to rotate;
said magnet in the inner ring of annular arrangement generating a magnetic field for controlling plasma near a circular inner region of the erosion surface of said target, said magnet in the outer ring of annular arrangement generating a magnetic field for controlling plasma near an outer region of the erosion surface of said target.

5. A magnetron unit according to claim 4, wherein said inner region of said erosion surface is a circular region, concentric with a wafer supported within a vacuum chamber in said sputtering apparatus having a diameter substantially identical to the diameter of said wafer; and wherein said outer region of said erosion surface is an annular region which is adjacent said inner region on the outside thereof and surrounds said inner region.
